(19) United States
(12) Patent Application Publication
(10) Pub. No.: US 2026/0129839 A1
(43) Pub. Date: May 7, 2026

(54) SEMICONDUCTOR DEVICE AND METHOD FOR FABRICATING THE SAME

(71) Applicant: SK hynix Inc., Gyeonggi-do (KR)

(72) Inventor: Sung Hwan HWANG, Gyeonggi-do (KR)

(21) Appl. No.: 19/223,036

(22) Filed: May 30, 2025

(30) Foreign Application Priority Data
Nov. 4, 2024 (KR) 10-2024-0154258

(51) Int. Cl. H10B 12/00

(52) U.S. Cl. CPC H10B 12/34; H10B 12/053

(57) ABSTRACT

A semiconductor device with improved Gate-Induced Drain Leakage (GIDL) and a method for fabricating the same are provided. The semiconductor device includes a trench formed in a substrate; a first gate dielectric layer suitable for covering a bottom surface and sidewalls of the trench; a first buried conductive layer suitable for filling a bottom portion of the trench over the first gate dielectric layer; a second buried conductive layer including a conductive metal oxide over the first buried conductive layer; and a second gate dielectric layer disposed between the second buried conductive layer and the first gate dielectric layer.

### CROSS-REFERENCE TO RELATED APPLICATIONS

The present application claims priority under 35 U.S.C 119(a) to Korean Patent Application No. 10-2024-0154258, filed on Nov. 4, 2024, which is incorporated herein by reference in its entirety.

### BACKGROUND

### 1. Field

Embodiments of the present disclosure relate generally to a semiconductor device and a fabrication method thereof, and, more particularly, to a semiconductor device including a buried gate, and a method for fabricating the semiconductor device.

### 2. Description of the Related Art

Metal gate electrodes are used to achieve high-performance transistors. For buried gate-type transistors, it is crucial to control the threshold voltage for optimal performance. Additionally, the Gate-Induced Drain Leakage (GIDL) characteristics significantly impact the performance of these transistors. However, as semiconductor devices become more integrated, improving GIDL characteristics becomes increasingly challenging.

### SUMMARY

Embodiments of the present disclosure are directed to a semiconductor device with improved Gate-Induced Drain Leakage (GIDL), and a method for fabricating the semiconductor device.

In accordance with an embodiment of the present disclosure, a semiconductor device includes a trench formed in a substrate; a first gate dielectric layer suitable for covering a bottom surface and sidewalls of the trench; a first buried conductive layer suitable for filling a bottom portion of the trench over the first gate dielectric layer; a second buried conductive layer including a conductive metal oxide over the first buried conductive layer; and a second gate dielectric layer disposed between the second buried conductive layer and the first gate dielectric layer.

In accordance with another embodiment of the present disclosure, a method for fabricating a semiconductor device includes forming a trench in a substrate; forming a first gate dielectric layer suitable for covering a bottom surface and sidewalls of the trench; forming a first buried conductive layer suitable for filling a bottom portion of the trench over the first gate dielectric layer; forming a dielectric oxide layer over the first buried conductive layer and the first gate dielectric layer; forming a second buried conductive layer over the dielectric oxide layer; and performing an annealing process to replace the dielectric oxide layer interposed between the first buried conductive layer and the second buried conductive layer with a conductive metal oxide, and to form the dielectric oxide layer interposed between the first gate dielectric layer and the second buried conductive layer as a second gate dielectric layer.

In accordance with another embodiment of the present disclosure, a semiconductor device includes a trench formed in a substrate; a first gate dielectric layer suitable for covering a bottom surface and sidewalls of the trench; a buried conductive layer including a conductive metal oxide in an upper portion of the first gate dielectric layer; and a second gate dielectric layer suitable for covering a portion of the first gate dielectric layer between the buried conductive layer and the first gate dielectric layer.

In accordance with another embodiment of the present disclosure, a semiconductor device includes a trench formed in a substrate; a first gate dielectric layer suitable for covering a bottom surface and sidewalls of the trench; a first buried conductive layer suitable for filling a bottom portion of the trench over the first gate dielectric layer; a conductive metal oxide electrode disposed in an upper portion of the first buried conductive layer, wherein the line width of the bottom surface of the conductive metal oxide electrode is wider than the line width of the top surface; a second buried conductive layer in an upper portion of the metal oxide electrode; and a second gate dielectric layer disposed between the metal oxide electrode and the second buried conductive layer and the first gate dielectric layer.

These and other features and advantages of the embodiments of the present disclosure will become apparent to those skilled in the art from the following detailed description in conjunction with the following drawings.

### BRIEF DESCRIPTION OF THE DRAWINGS

FIG. 1A is a plan view illustrating a semiconductor device in accordance with an embodiment of the present disclosure.

FIGS. 1B and 1C are cross-sectional views illustrating the semiconductor device in accordance with an embodiment of the present disclosure.

FIGS. 2A to 2G are process cross-sectional views illustrating a method for fabricating a semiconductor device in accordance with an embodiment of the present disclosure.

FIGS. 3A to 3G are process cross-sectional views illustrating a method for fabricating a semiconductor device in accordance with another embodiment of the present disclosure.

FIGS. 4A to 4H are process cross-sectional views illustrating a method for fabricating a semiconductor device in accordance with yet another embodiment of the present disclosure.

FIG. 5A is a plan view illustrating a semiconductor device in accordance with another embodiment of the present disclosure.

FIG. 5B is a cross-sectional view illustrating the semiconductor device in accordance with an embodiment of the present disclosure.

### DETAILED DESCRIPTION

Embodiments of the present disclosure will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments.

Hereinafter, the various embodiments of the present disclosure will be described in detail with reference to the attached drawings.

The drawings are not necessarily to scale and in some instances, proportions may have been exaggerated to clearly illustrate features of the embodiments. When a first layer is referred to as being ‘on’ a second layer or ‘on’ a substrate, it not only refers to a case where the first layer is formed directly on the second layer or the substrate but also a case where a third layer exists between the first layer and the second layer or the substrate.

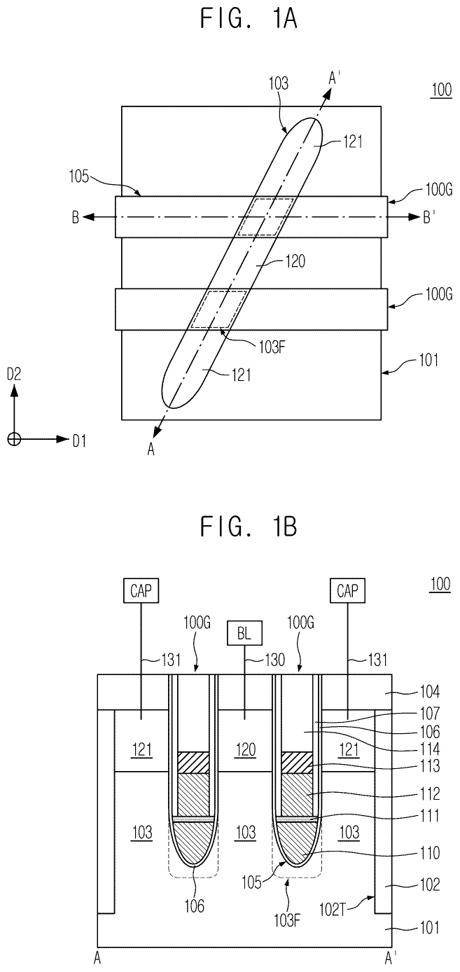

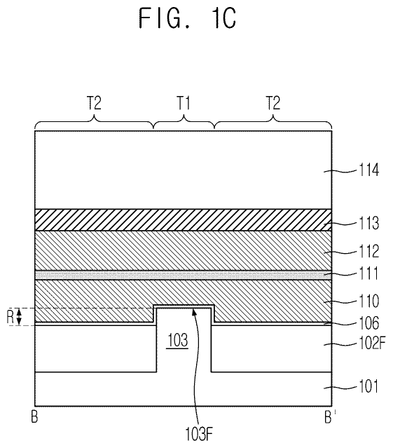

FIG. 1A is a plan view illustrating a semiconductor device in accordance with an embodiment of the present disclosure. FIGS. 1B and 1C are cross-sectional views illustrating the semiconductor device in accordance with an embodiment of the present disclosure. FIG. 1B is a cross-sectional view taken along a line A-A′ shown in FIG. 1A. FIG. 1C is a cross-sectional view taken along a line B-B′ shown in FIG. 1A.

Referring to FIGS. 1A to 1C, the semiconductor device 100 may include a substrate 101 and a buried gate structure 100G embedded in the substrate 101, a first doped region 120, and a second doped region 121. The buried gate structure 100G and the first and second doped regions 120 and 121 may constitute a cell transistor. The cell transistor may improve the short channel effect due to the buried gate structure.

The semiconductor device 100 may be a portion of a memory cell. For example, the semiconductor device 100 may be a portion of a memory cell of a Dynamic Random Access Memory (DRAM). The semiconductor device 100 may include a bit line BL and a memory storage element CAP that are electrically connected to the substrate 101.

The bit line BL may be electrically connected to the first doped region 120. The memory storage elements CAP may be electrically connected to the second doped regions 121. The bit line BL may be electrically connected to the first doped region 120 through a bit line node 130. Each of the memory storage elements CAP may be electrically connected to a corresponding second doped region 121 through a storage node 131. The bit line BL and the memory storage elements CAP may be disposed at a higher level than the buried gate structure 100G. The bit line BL and the memory storage elements CAP may be disposed at different levels. The memory storage elements CAP may be disposed at a higher level than the bit line BL. The memory storage elements CAP may include a capacitor.

The substrate 101 may be any material that is appropriate for semiconductor processing. The substrate 101 may include a semiconductor substrate. The substrate 101 may be formed of a material containing silicon. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may also include other semiconductor materials, such as germanium. The substrate 101 may include a III/V-group semiconductor substrate, for example, a compound semiconductor substrate, such as gallium arsenide (GaAs). The substrate 101 may also include a SOI (Silicon-On-Insulator) substrate.

An isolation layer 102 and active regions 103 may be formed over the substrate 101. The active regions 103 may be defined by the isolation layer 102. The active regions 103 may have a major axis and a minor axis. The active regions 103 may be tilted in a diagonal direction. A pair of buried gate structures 100G spaced apart from each other may be formed in one active region 103. Each active region 103 may include a first conductive region 120 disposed between the pair of the buried gate structures 100G in the active region 103. Each active region 103 may include a pair of second conductive regions 121 that are disposed in the outside of each buried gate structure 100G. This embodiment of the present disclosure may present a ‘6F2’ structure that includes a pair of buried gate structures 200G, one first conductive region 120, and two second conductive regions 121 in one active region. The term ‘6F2’ refers to the cell size of the DRAM, where ‘F’ represents the feature size, and ‘6F2’ indicates that the cell occupies an area of 6 times the square of the feature size.

The isolation layer 102 may be a Shallow Trench Isolation (STI) region which is formed by a trench etching process. The isolation layer 102 may be formed by first forming a shallow trench 102T, and then filling the shallow trench 102T with a dielectric material to form the isolation layer 102. The isolation layer 102 may include silicon oxide, silicon nitride, or a combination thereof.

Another trench 105 may be formed in the substrate 101 by first using a hard mask layer 104 as an etching barrier and then etching the substrate 101. The trench 105 may be a space where the buried gate structure 100G is formed and may be referred to as a ‘gate trench 105’. From the plan view perspective of FIG. 1A, the trench 105 may have a line shape extending in a first direction D1. The trench 105 may be of a line shape that crosses the active regions 103 and the isolation layer 102. A plurality of gate trenches 105 may be formed and may be spaced apart from each other in a second direction D2. The first direction D1 and the second direction D2 may be orthogonal to each other. The trench 105 may have a shallower depth than the isolation trench 102T. The bottom portion of the trench 105 may have a curvature.

According to an embodiment of the present disclosure, two gate trenches 105 may be disposed parallel side by side to each other and may be spaced apart from each other in each active region 103. Since each buried gate structure 100G provided in the inside of each trench 105 may serve as a gate of a transistor, two transistors may be provided in each active region 103.

A first doped region 120 and a second doped region 121 may be formed in each active region 103. The first and second doped regions 120 and 121 may be doped with a conductive dopant, including, for example, phosphorus (P), arsenic (As), antimony (Sb), or boron (B), or any combination thereof. The first and second doped regions 120 and 121 may be doped with a dopant of the same conductivity type. The first and second doped regions 120 and 121 may be disposed in each active region 103 on both sides of the trench 105. Each pair of a first doped region 120 and its adjacent second doped region 121 may be spaced apart from each other by trench 105. The bottom surfaces of the first and second doped regions 120 and 121 may be disposed at a predetermined depth from the top surface of each active region 103. The bottom surfaces of the first and second doped regions 120 and 121 may be higher than the bottom surface of the trench 105. The first doped region 120 may be referred to as a ‘first source/drain region 120’, and the second doped region 121 may be referred to as a ‘second source/drain region 121’. A channel may be defined between the first doped region 120 and the second doped region 121 by the buried gate structure 100G. The channel may be defined along the profile of the trench 105.

According to an embodiment of the present disclosure, one first doped region 120 and a pair of second doped regions 121 may be disposed in each active region 103. The first doped region 120 may be disposed between the pair of second doped regions 121. Two transistors may be provided in each active region 103. The two transistors disposed in each active region 103 may be coupled to a common source line, i.e., the same first doped region 120.

The trench 105 may include a first trench T1 and a second trench T2. The first trench T1 may be formed in the active region 103. The second trench T2 may be formed in the isolation layer 102. The trench 105 may continuously extend from the first trench T1 to the second trench T2. In the trench 105, the bottom surface of the first trench T1 may be disposed at a higher level than the bottom surface of the second trench T2. The step height between the first trench T1 and the second trench T2 may be formed as the isolation layer 102 is recessed. Therefore, the second trench T2 may include a recessed region R whose bottom surface is lower than the bottom surface of the first trench T1. A fin region 103F may be formed in the active region 103 due to the step height between the first trench T1 and the second trench T2. Therefore, each active region 103 may include a fin region 103F.

As described, the fin region 103F may be formed below the first trench T1, and a sidewall of the fin region 103F may be exposed by the recessed isolation layer 102F. The fin region 103F may be a portion where a portion of a channel (not shown) is formed. The fin region 103F may be referred to as a saddle fin. The channel width may be increased by the fin region 103F, and the electrical characteristics may be improved.

According to another embodiment of the present disclosure, the fin region 103F may be omitted.

The buried gate structure 100G may be embedded in the trench 105.

The buried gate structure 100G may include a first gate dielectric layer 106 covering the bottom surface and sidewall of the trench 105, a second gate dielectric layer 107 overlapping with a portion of the sidewall of the trench 105 on the sidewall of the first gate dielectric layer 106, a first metal gate electrode 110 filling a lower portion of the trench 105 over the first gate dielectric layer, a metal oxide electrode 111 over the first metal gate electrode 110, a second metal gate electrode 112 over the metal oxide electrode 111, a semiconductor gate electrode 113 over the second metal gate electrode 112, and a gate capping layer 114 formed over the semiconductor gate electrode 113.

The first gate dielectric layer 106 may be conformally formed along the bottom surface and inner wall of the trench 105. The first gate dielectric layer 106 may include silicon oxide, silicon nitride, silicon oxynitride, a high-k material, or a combination thereof. The high-k material may include a material having a greater dielectric constant than the dielectric constant of silicon oxide. For example, the high-k material may include a material having a greater dielectric constant than approximately 3.9. For another example, the high-k material may include a material having a greater dielectric constant than approximately 10. For another example, the high-k material may include a material having a dielectric constant of approximately 10 to 30. The high-k material may include at least one metallic element. The high-k material may include a hafnium-containing material. The hafnium-containing material may include hafnium oxide, hafnium silicon oxide, hafnium silicon oxynitride, or a combination thereof. According to another embodiment of the present disclosure, the high-k material may include lanthanum oxide, lanthanum aluminum oxide, zirconium oxide, zirconium silicon oxide, zirconium silicon oxynitride, aluminum oxide, or a combination thereof. Other known high-k materials may be selectively used as the high-k material. The first gate dielectric layer 106 may include a metal oxide.

The first metal gate electrode 110 may fill a portion of the trench 105. The first metal gate electrode 110 may include a metal or a metal nitride. For example, the metal may include a low-resistance metal material, such as molybdenum (Mo), tantalum (Ta), and titanium (Ti). For example, the metal nitride may include titanium nitride (TiN). The outer wall of the first metal gate electrode 110 may be covered by the first gate dielectric layer 106. That is, only the first gate dielectric layer 106 may remain between the first metal gate electrode 110 and the inner wall of the trench 105.

The metal oxide electrode 111 may be disposed in the upper portion of the first metal gate electrode 110. The metal oxide electrode 111 may be a conductive material including the same metal as the first and second metal gate electrodes 110 and 112. The thickness of the metal oxide electrode 111 may be thinner than the thickness of each of the first and second metal gate electrodes 110 and 112.

For example, when the first metal gate electrode 110 is titanium nitride (TiN), the metal oxide electrode 111 may be conductive titanium oxide (TiₓO_{y}), but the embodiments of the present disclosure are not limited thereto.

Both sides of the metal oxide electrode 111 may contact the second gate dielectric layer 107. More specifically, the second gate dielectric layer 107 may contact the side edge portions of the top surface of the metal oxide electrode 111. The first and second gate dielectric layers 106 and 107 may be disposed between the metal oxide electrode 111 and the inner wall of the trench 105.

A second metal gate electrode 112 may be formed over the metal oxide electrode 111. The second metal gate electrode 112 may be the same material as that of the first metal gate electrode 110. For example, the second metal gate electrode 112 may include titanium nitride.

A semiconductor gate electrode 113 may be formed over the second metal gate electrode 112. For example, the semiconductor gate electrode 113 may include polysilicon. The thickness of the semiconductor gate electrode 113 may be thinner than the thickness of each of the first and second metal gate electrodes 110 and 112. The semiconductor gate electrode 113 may be thicker than the metal oxide electrode 111.

The semiconductor gate electrode 113 may overlap with the first and second doped regions 120 and 121 in a direction parallel to the surface of the substrate 101.

A gate capping layer 114 may be formed over the semiconductor gate electrode 113. The gate capping layer 114 may prevent oxidation of the semiconductor gate electrode 113. The gate capping layer 114 may be formed in the trench 105 to electrically insulate an upper structure such as a contact and a conductive line from a lower gate electrode. According to an embodiment of the present disclosure, the upper surface of the gate capping layer 114 may be disposed at the same level as the upper surface of the hard mask layer 104. According to another embodiment of the present disclosure, the upper surface of the gate capping layer 114 may be disposed at the same level as the upper surface of the substrate 101.

The gate capping layer 114 may include a dielectric material. The gate capping layer 114 may include silicon nitride or silicon oxide, but the embodiments of the present disclosure are not limited thereto. According to another embodiment of the present disclosure, the gate capping layer 114 may include a low-k material. The gate capping layer 114 may be formed as a single layer. According to another embodiment of the present disclosure, the gate capping layer 114 may be formed as a multi-layer structure of different materials.

The second gate dielectric layer 107 may contact the metal oxide electrode 111, and both sidewalls of the second metal gate electrode 112, the semiconductor gate electrode 113 and the gate capping layer 114. The second gate dielectric layer 107 may be disposed between the metal oxide electrode 111, the second metal gate electrode 112 and the semiconductor gate electrode 113, and the inner surface of the trench 105. The second gate dielectric layer 107 may include the same material as that of the first gate dielectric layer 106. For example, the second gate dielectric layer 107 may include silicon oxide.

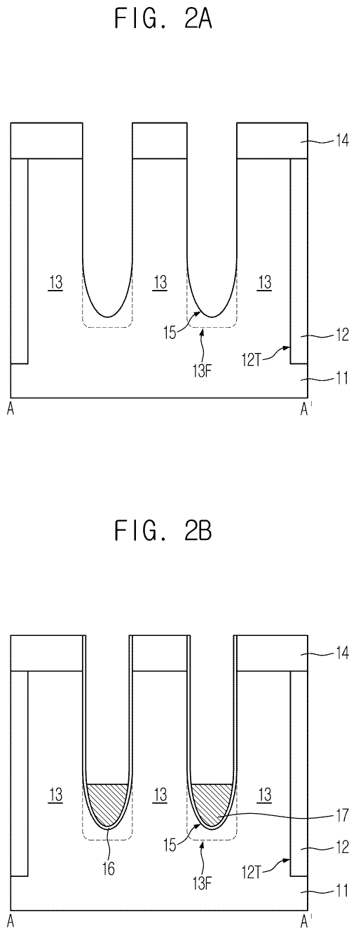

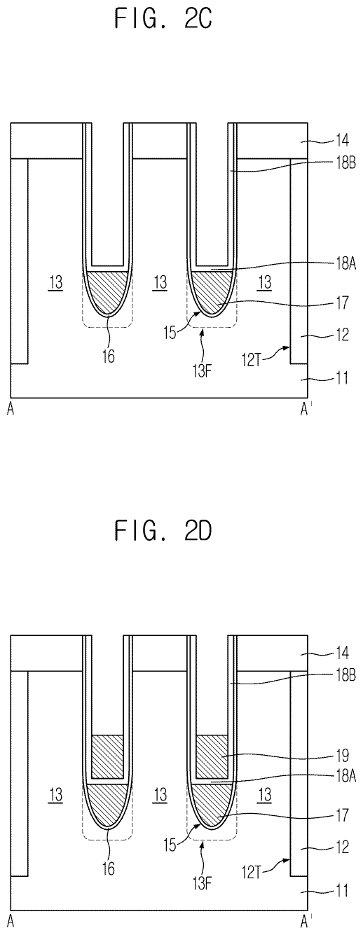

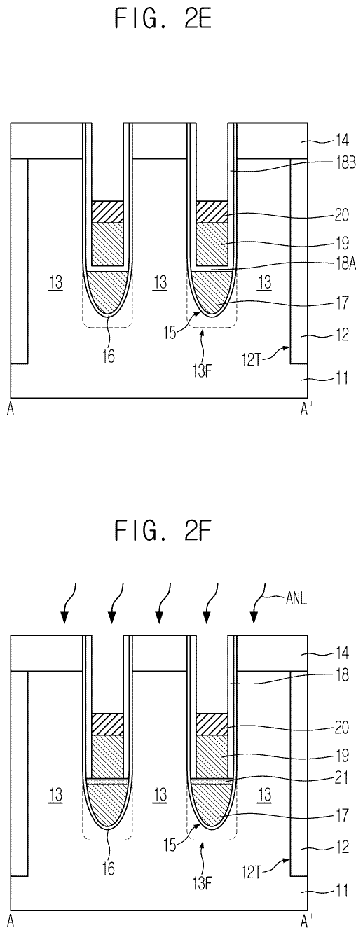

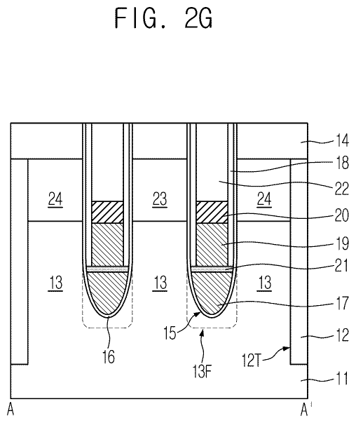

FIGS. 2A to 2G are process cross-sectional views illustrating a method for fabricating a semiconductor device in accordance with an embodiment of the present disclosure. FIGS. 2A to 2G are process cross-sectional views taken along a line A-A′ shown in FIG. 1A.

Referring to FIG. 2A, an isolation layer 12 may be formed in a substrate 11. An active region 14 may be defined by the isolation layer 12. The isolation layer 12 may be formed by a Shallow Trench Isolation region (STI) process. For example, the substrate 11 may be etched to form an isolation trench 12T. The isolation trench 12T may be filled with a dielectric material, thereby forming the isolation layer 12. The isolation layer 12 may include silicon oxide, silicon nitride, or a combination thereof. Chemical Vapor Deposition (CVD) or another deposition process may be used to fill the isolation trench 12T with the dielectric material. A planarization process, such as a Chemical-Mechanical Polishing (CMP) process, may be additionally performed.

A trench 15 may be formed in the substrate 11. The trench 15 may be formed in a line shape crossing the active region 13 and the isolation layer 12. The trench 15 may be a space where a buried gate structure is formed and may be referred to also as gate trench 15. The trench 15 may be formed by an etching process of the substrate 11 using the hard mask layer 14 as an etching mask. The hard mask layer 14 may be formed over the substrate 11 and may have a line-shaped opening. The hard mask layer 14 may be formed of a material having an etching selectivity with respect to the substrate 11. The hard mask layer 14 may be silicon oxide, such as, for example, TEOS (Tetra-Ethyl-Ortho-Silicate). The trench 15 may be formed shallower than the isolation trench 12T. The depth of the trench 15 may be sufficiently deep to increase the average cross-sectional area of the subsequent gate electrode. Accordingly, the resistance of the gate electrode may be reduced. The bottom edge of the trench 15 may have a curvature.

Subsequently, a fin region 13F may be formed. To form the fin region 13F, the isolation layer 12 below the trench 15 may be selectively recessed. The structure of the fin region 13F may be the same as that of the fin region 103F of FIG. 1B described earlier.

Referring to FIG. 2B, a gate dielectric layer 16 may be formed on the surface of the trench 15. Before the gate dielectric layer 16 is formed, etching damage on the surface of the trench 15 may be cured. For example, after a sacrificial oxide is formed by a thermal oxidation process, the sacrificial oxide may be removed.

The gate dielectric layer 16 may be formed by a thermal oxidation process. The gate dielectric layer 16 may include silicon oxide.

According to another embodiment of the present disclosure, the gate dielectric layer 16 may be formed by a Chemical Vapor Deposition (CVD) process or an Atomic Layer Deposition (ALD) process. The gate dielectric layer 16 formed by a deposition method may include a high-k material, an oxide, a nitride, an oxynitride, or a combination thereof. The high-k material may include a hafnium-containing material. The hafnium-containing material may include hafnium oxide, hafnium silicon oxide, hafnium silicon oxynitride, or a combination thereof. According to another embodiment of the present disclosure, the high-k material may include lanthanum oxide, lanthanum aluminum oxide, zirconium oxide, zirconium silicon oxide, zirconium silicon oxynitride, aluminum oxide, or a combination thereof. Other known high-k materials may be selectively used as the high-k material. The gate dielectric layer 16 may include a material having a high oxygen atomic planar density.

Subsequently, a first metal gate electrode 17 may be formed over the gate dielectric layer 16.

The first metal gate electrode 17 may be formed by a series of processes of forming a first conductive material to fill the trench 15 in the upper portion of the gate dielectric layer 16, and performing a recess process onto the first conductive material. The recess process may include a dry etching process, for example, an etch-back process.

For example, the first metal gate electrode 17 may include titanium nitride (TIN). According to an embodiment, the first metal gate electrode 17 may be formed by an Atomic Layer Deposition (ALD) process. In another embodiment, the first metal gate electrode 17 may be formed by a Chemical Vapor Deposition (CVD) process. According to an embodiment of the present disclosure, the first metal gate electrode 17 may include a stacked structure of a metal nitride excluding titanium nitride or a metal nitride including titanium nitride. According to an embodiment of the present disclosure, the first metal gate electrode 17 may include a metal material. For example, the metal may include a low-resistance metal material, such as molybdenum (Mo), tantalum (Ta), and titanium (Ti).

Referring to FIG. 2C, a dielectric oxide layer 18A and 18B may be formed over the first metal gate electrode 17 and the first gate dielectric layer 16 that is exposed by the first metal gate electrode 17. The dielectric oxide layer 18A and 18B may be formed conformally with a uniform thickness in the upper portion of the first metal gate electrode 17 and the upper portion of the sidewall of the first gate dielectric layer 16. The dielectric oxide layer 18A and 18B may include a first portion 18A disposed in the upper portion of the first metal gate electrode 17, and a second portion 18B disposed in the upper portion of the sidewall of the first gate dielectric layer 16. The first portion 18A and the second portion 18B may have a single structure extending continuously. The first portion 18A and the second portion 18B may have a single U-shape structure extending continuously.

For example, the dielectric oxide layer 18A and 18B may be formed by a plasma oxidation process. The plasma oxidation process may cause only surface oxidation of the first metal gate electrode 17, and deterioration in the resistance that may be caused due to the oxidation may not occur. Also, the plasma oxidation process may have a lower oxygen enhanced diffusion (OED) effect than that of a thermal oxidation process, preventing junction leakage current.

According to another embodiment of the present disclosure, the dielectric oxide layer 18A and 18B may be formed through a deposition process, a radical oxidation process, or an ion implantation process.

Referring to FIG. 2D, a second metal gate electrode 19 may be formed over the first portion 18A of the dielectric oxide layer. The second metal gate electrode 19 may be formed by a series of processes of forming a second conductive material that fills the trench 15 over the first portion 18A of the dielectric oxide layer, and then performing a recess process onto the second conductive material. The recess process may include a dry etching process, for example, an etch-back process.

The second metal gate electrode 19 may include the same metal as that of the first metal gate electrode 17. The second metal gate electrode 19 may include a metal or a metal nitride. For example, the metal may include a low-resistance metal material, such as molybdenum (Mo), tantalum (Ta), and titanium (Ti). For example, the metal nitride may include titanium nitride (TiN) and may be formed by an Atomic Layer Deposition (ALD) process or a Chemical Vapor Deposition (CVD) process.

Referring to FIG. 2E, a semiconductor gate electrode 20 may be formed over the second metal gate electrode 19. The semiconductor gate electrode 20 may have a top surface positioned below a top surface of the substrate 11. The semiconductor gate electrode 20 may include a conductive semiconductor material. For example, the semiconductor gate electrode 20 may include a polysilicon material.

Referring to FIG. 2F, an annealing process indicated by the arrows ANL may be performed. Therefore, the first portion 18A (see FIG. 2E) of the dielectric oxide layer disposed between the first and second metal gate electrodes 17 and 19 may be replaced with a conductive metal oxide electrode 21. For example, the annealing process ANL may be performed in an atmosphere of N₂, O₂, NH₃, H₂, SiH₄, or a mixed gas thereof.

The metal oxide electrode 21 may be replaced with a conductive metal oxide as the metal in the first and second metal gate electrodes 17 and 19 and the oxygen in the first portion 18A of the dielectric oxide layer are diffused into each other by the annealing process ANL. Also, the first and second metal gate electrodes 17 and 19 may be crystallized by the annealing process ANL. Furthermore, the first and second metal gate electrodes 17 and 19 may have an effect of increasing a flat band voltage Vfb through oxygen absorption during the annealing process ANL.

The thickness of the metal oxide electrode 21 may be thinner than the thickness of the first portion 18A of the dielectric oxide. The thickness of the metal oxide electrode 21 may be thinner than the thicknesses of the first and second metal gate electrodes 17 and 19.

The second portion 18B (see FIG. 2E) of the dielectric oxide excluding the metal oxide electrode 21 may be the second gate dielectric layer 18.

Referring to FIG. 2G, a gate capping layer 22 that gap-fills the remaining portion of the trench 15 may be formed over the semiconductor gate electrode 20. The gate capping layer 22 may be formed by a series of processes of forming a dielectric material that gap-fills the trench 15 over the semiconductor gate electrode 22 and etching the dielectric material targeting to expose the surface of the hard mask layer 14. For example, the etching process may be performed as a planarization process. For example, the planarization process may include a Chemical Mechanical Polishing (CMP) process or an etch-back process.

For example, the gate capping layer 22 may include silicon nitride or silicon oxide.

Subsequently, the first and second doped regions 23 and 24 may be formed through impurity ion implantation into the substrate 11, i.e., the active region 13.

As described above, according to this embodiment of the present disclosure, a second gate dielectric layer 18 may be additionally formed on a portion of the sidewall of the first gate dielectric layer 16 to prevent the Gate-Induced Drain Leakage by increasing the actual thickness of the gate dielectric layer. Also, the etch-back etching height of the second metal gate electrode 19 may be reduced.

As a comparative example, when the second gate dielectric layer 18 is not applied, it is necessary to control the etch-back thickness such that the second metal gate electrode 19 does not overlap with the first and second conductive regions 23 and 24 due to the gate-induced drain leakage. That is, it is necessary to control the upper surface of the second metal gate electrode 19 to be disposed at a lower level than the lower surfaces of the first and second conductive regions 23 and 24.

However, according to the embodiment of the present disclosure, even though the second metal gate electrode 19 overlaps with the first and second conductive regions 23 and 24 in the horizontal direction, the gate-induced drain leakage may be prevented due to the increase in the thickness of the gate dielectric layer. Therefore, the etch-back etching height may be reduced, securing a process margin. Also, when the etch-back etching height of the second metal gate electrode 19 is decreased, the total volume of the metal gate electrode may be increased, which may lead to a reduction in device resistance.

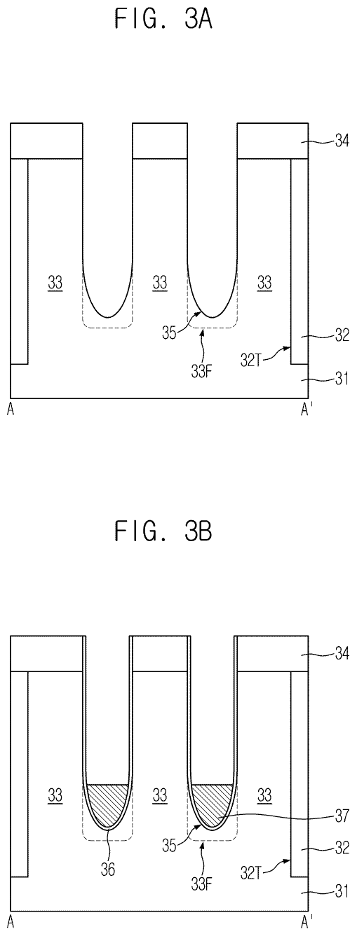

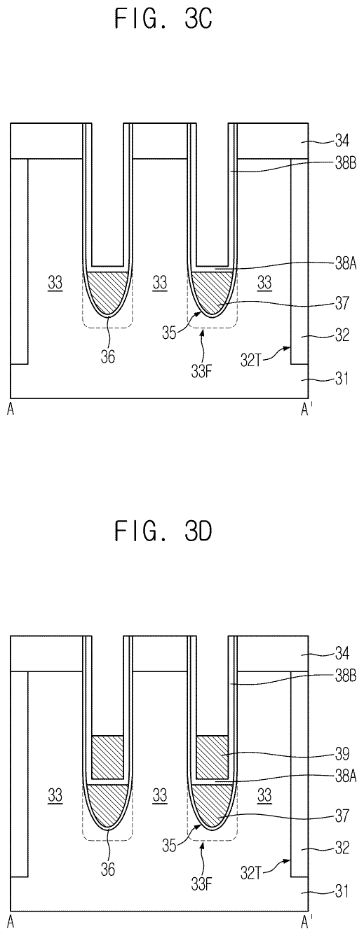

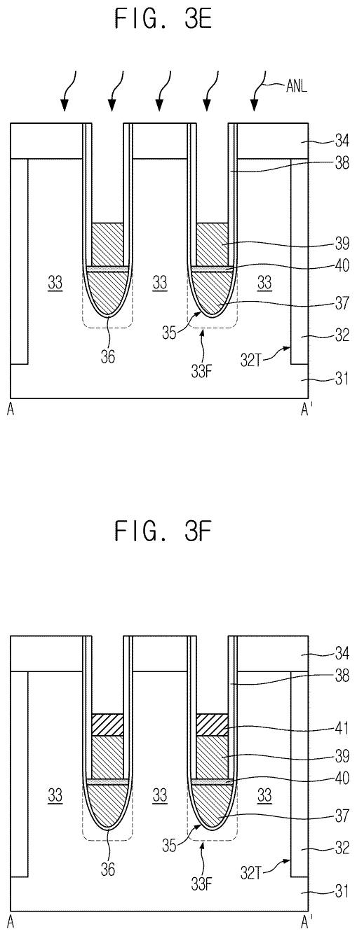

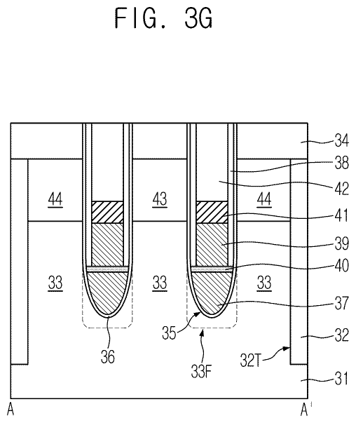

FIGS. 3A to 3G are process cross-sectional views illustrating a method for fabricating a semiconductor device in accordance with another embodiment of the present disclosure. FIGS. 3A to 3G may be performed in the same or similar process as FIGS. 2A to 2G, except for the annealing process sequence.

Referring to FIG. 3A, an isolation layer 32 may be formed in a substrate 31. An active region 34 may be defined by the isolation layer 32. The isolation layer 32 may be formed by a Shallow Trench Isolation (STI) process. For example, the substrate 31 may be etched to form an isolation trench 32T. The isolation trench 32T may be filled with a dielectric material, thereby forming the isolation layer 32. The isolation layer 32 may include silicon oxide, silicon nitride, or a combination thereof. Chemical Vapor Deposition (CVD) or another deposition process may be used to fill the isolation trench 32T with the dielectric material. A planarization process such as a Chemical-Mechanical Polishing (CMP) process may be additionally performed.

A trench 35 may be formed in the substrate 31. The trench 35 may be formed in a line shape crossing the active region 33 and the isolation layer 32. The trench 35 may be formed by an etching process of the substrate 31 using the hard mask layer 34 as an etching mask. The hard mask layer 34 may be formed over the substrate 31 and may have a line-shaped opening, for example, a plurality of line-shaped openings. The hard mask layer 34 may be formed of a material having an etching selectivity with respect to the substrate 31. The hard mask layer 34 may be of silicon oxide, such as, for example, Tetra-Ethyl-Ortho-Silicate (TEOS). The trench 35 may be formed shallower than the isolation trench 32T. The depth of the trench 35 may be sufficiently deep to increase the average cross-sectional area of the subsequent gate electrode. Accordingly, the resistance of the gate electrode may be decreased. The bottom edge of the trench 35 may have a curvature.

Subsequently, a fin region 33F may be formed. To form the fin region 33F, the isolation layer 32 below the trench 35 may be selectively recessed. The structure of the fin region 33F may be the same as the structure of the fin region 103F of FIG. 1B described earlier.

Referring to FIG. 3B, a gate dielectric layer 36 may be formed on the surface of the trench 35. Before the gate dielectric layer 36 is formed, etching damage on the surface of the trench 35 may be cured. For example, after a sacrificial oxide is formed by a thermal oxidation process, the sacrificial oxide may be removed.

The gate dielectric layer 36 may be formed by a thermal oxidation process. The gate dielectric layer 36 may include silicon oxide.

According to another embodiment of the present disclosure, the gate dielectric layer 36 may be formed by Chemical Vapor Deposition (CVD) or Atomic Layer Deposition (ALD). The gate dielectric layer 36 formed by the deposition method may include a high-k material, an oxide, a nitride, an oxynitride, or a combination thereof. The high-k material may include a hafnium-containing material. The hafnium-containing material may include hafnium oxide, hafnium silicon oxide, hafnium silicon oxynitride, or a combination thereof. According to another embodiment of the present disclosure, the high-k material may include lanthanum oxide, lanthanum aluminum oxide, zirconium oxide, zirconium silicon oxide, zirconium silicon oxynitride, aluminum oxide, or a combination thereof. Other known high-k materials may be selectively used as the high-k material. The gate dielectric layer 36 may include a material having a high oxygen atomic planar density.

Subsequently, a first metal gate electrode 37 may be formed over the gate dielectric layer 36.

The first metal gate electrode 37 may be formed by a series of processes of forming a first conductive material that fills the trench 35 in the upper portion of the gate dielectric layer 36, and then performing a recess process onto the first conductive material. The recess process may include a dry etching process, for example, an etch-back process.

For example, the first metal gate electrode 37 may include titanium nitride (TIN). The first metal gate electrode 37 may be formed, for example, by an Atomic Layer Deposition (ALD) process or a Chemical Vapor Deposition (CVD) process. According to another embodiment of the present disclosure, the first metal gate electrode 37 may include a stacked structure of a metal nitride excluding titanium nitride or a metal nitride including titanium nitride. According to another embodiment of the present disclosure, the first metal gate electrode 37 may include a metal material. For example, the metal may include a low-resistance metal material, such as molybdenum (Mo), tantalum (Ta), and titanium (Ti).

Referring to FIG. 3C, a dielectric oxide layer 38A and 38B may be formed over the first metal gate electrode 37 and the first gate dielectric layer 36 that is exposed by the first metal gate electrode 37. The dielectric oxide layer 38A and 38B may be formed conformally with a uniform thickness in the upper portion of the first metal gate electrode 37 and the upper portion of the sidewall of the first gate dielectric layer 36. The dielectric oxide layer 38A and 38B may include a first portion 38A disposed over the first metal gate electrode 37, and a second portion 38B disposed in the upper portion of the sidewall of the first gate dielectric layer 36. The first portion 38A and the second portion 38B may be a single structure that extends continuously.

For example, the dielectric oxide layer 38A and 38B may be formed by a plasma oxidation process. The plasma oxidation process may cause only surface oxidation of the first metal gate electrode 37, and deterioration in the resistance that may be caused due to the oxidation may not occur. Also, the plasma oxidation process may have a lower oxygen enhanced diffusion (OED) effect than that of a thermal oxidation process, preventing junction leakage current.

According to another embodiment of the present disclosure, the dielectric oxide layer 38A and 38B may be formed through a deposition process, a radical oxidation process, or an ion implantation process.

Referring to FIG. 3D, a second metal gate electrode 39 may be formed over the first portion 38A of the dielectric oxide layer. The second metal gate electrode 39 may be formed by a series of processes of forming a second conductive material that fills the trench 35 over the first portion 38A of the dielectric oxide layer, and then performing a recess process onto the second conductive material. The recess process may include a dry etching process, for example, an etch-back process.

The second metal gate electrode 39 may include the same metal as the first metal gate electrode 37. The second metal gate electrode 39 may include a metal or a metal nitride. For example, the metal material may include a low-resistance metal material, such as molybdenum (Mo), tantalum (Ta), and titanium (Ti). For example, the metal nitride may include titanium nitride (TIN). The second metal gate electrode 39 may be formed by an Atomic Layer Deposition (ALD) process or a Chemical Vapor Deposition (CVD) process.

Referring to FIG. 3E, an annealing process indicated by the arrows ANL may be performed. Accordingly, the first portion 38A (see FIG. 3D) of the dielectric oxide layer disposed between the first and second metal gate electrodes 37 and 39 may be replaced with a conductive metal oxide electrode 40. For example, the annealing process ANL may be performed in an atmosphere of N₂, O₂, NH₃, H₂, SiH₄, or a mixed gas thereof.

The metal oxide electrode 40 may be replaced with a conductive metal oxide, as the metal in the first and second metal gate electrodes 37 and 39 and the oxygen in the first portion 38A of the dielectric oxide layer are diffused into each other by the annealing process ANL. Also, the first and second metal gate electrodes 37 and 39 may be crystallized by the annealing process ANL. Furthermore, the first and second metal gate electrodes 37 and 39 may have an effect of increasing the flat band voltage Vfb through oxygen absorption during the annealing process ANL.

The thickness of the metal oxide electrode 40 may be thinner than the thickness of the first portion 38A of the dielectric oxide. The thickness of the metal oxide electrode 40 may be thinner than the thickness of the first and second metal gate electrodes 37 and 39.

The second portion 38B (see FIG. 3D) of the dielectric oxide excluding the metal oxide electrode 40 may be the second gate dielectric layer 38.

Referring to FIG. 3F, a semiconductor gate electrode 41 may be formed over the second metal gate electrode 39. A top surface of the semiconductor gate electrode 41 may be lower than the top surface of the substrate 31. The semiconductor gate electrode 41 may include a conductive semiconductor material. For example, the semiconductor gate electrode 41 may include a polysilicon material.

Referring to FIG. 3G, a gate capping layer 42 may be formed to gap-fill the trench 35 over the semiconductor gate electrode 41. Forming the gate capping layer 42 may include forming a dielectric material that gap-fills the trench 35 over the semiconductor gate electrode 41, and etching the dielectric material targeting to expose the surface of the hard mask layer 34. For example, the etching process may include a planarization process, such as, for example, a Chemical Mechanical Polishing (CMP) process or an etch-back process.

For example, the gate capping layer 42 may include silicon nitride or silicon oxide.

Subsequently, the first and second doped regions 43 and 44 may be formed through an impurity ion implantation process of implanting an impurity into the substrate 31, i.e., the active region 33.

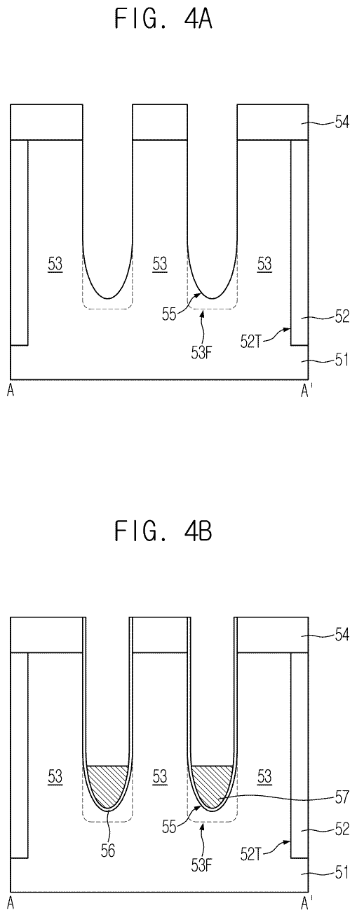

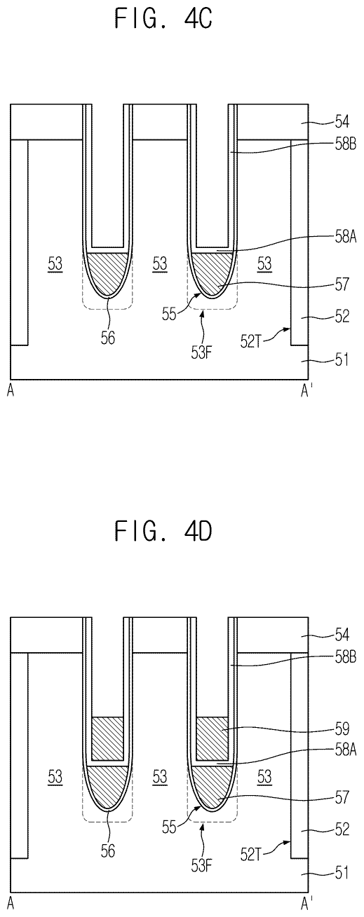

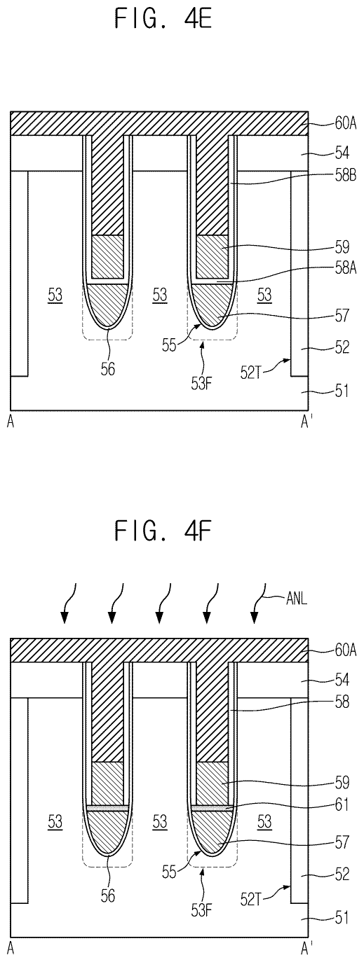

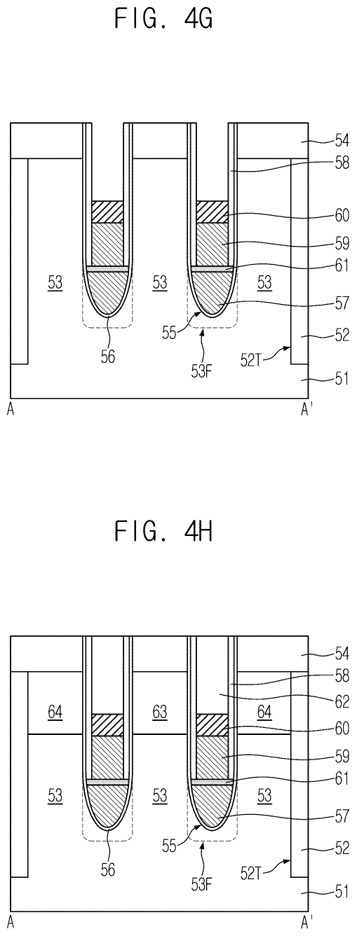

FIGS. 4A to 4H are process cross-sectional views illustrating a method for fabricating a semiconductor device in accordance with yet another embodiment of the present disclosure.

Referring to FIG. 4A, an isolation layer 52 may be formed in a substrate 51 to define an active region 53 in the substrate 51. The isolation layer 52 may be formed by a Shallow Trench Isolation region (STI) process. For example, the substrate 51 may be etched to form an isolation trench 52T. The isolation trench 52T may be filled with a dielectric material, thereby forming the isolation layer 52. The isolation layer 52 may include silicon oxide, silicon nitride, or a combination thereof. Chemical vapor deposition (CVD) or another deposition process may be used to fill the isolation trench 52T with the dielectric material. A planarization process such as a Chemical-Mechanical Polishing (CMP) process may be additionally performed.

A trench 55 may be formed in the substrate 51. The trench 55 may be formed in a line shape crossing the active region 53 and the isolation layer 52. The trench 55 may be formed by an etching process of the substrate 51 using the hard mask layer 54 as an etching mask. The hard mask layer 54 may be formed over the substrate 51 and may have a line-shaped opening. The hard mask layer 54 may be formed of a material having an etching selectivity with respect to the substrate 51. The hard mask layer 54 may be silicon oxide, such as Tetra-Ethyl-Ortho-Silicate (TEOS). The trench 55 may be formed shallower than the isolation trench 52T. The depth of the trench 55 may be sufficiently deep to increase the average cross-sectional area of the subsequent gate electrode. Accordingly, the resistance of the gate electrode may be decreased. The bottom edge of the trench 55 may have a curvature.

Subsequently, a fin region 53F may be formed. To form the fin region 53F, the isolation layer 52 below the trench 55 may be selectively recessed. The structure of the fin region 53F may be the same as the structure of the fin region 103F of FIG. 1B described above.

Referring to FIG. 4B, a gate dielectric layer 56 may be formed on the surface of the trench 55. Before the gate dielectric layer 56 is formed, etching damage on the surface of the trench 55 may be cured. For example, after a sacrificial oxide is formed by a thermal oxidation process, the sacrificial oxide may be removed.

The gate dielectric layer 56 may be formed by a thermal oxidation process. The gate dielectric layer 56 may include silicon oxide.

According to another embodiment of the present disclosure, the gate dielectric layer 56 may be formed by Chemical Vapor Deposition (CVD) or Atomic Layer Deposition (ALD). The gate dielectric layer 56 formed by the deposition method may include a high-k material, an oxide, a nitride, an oxynitride, or a combination thereof. The high-k material may include a hafnium-containing material. The hafnium-containing material may include hafnium oxide, hafnium silicon oxide, hafnium silicon oxynitride, or a combination thereof. According to another embodiment of the present disclosure, the high-k material may include lanthanum oxide, lanthanum aluminum oxide, zirconium oxide, zirconium silicon oxide, zirconium silicon oxynitride, aluminum oxide, or a combination thereof. Other known high-k materials may be selectively used as the high-k material. The gate dielectric layer 56 may include a material having a high oxygen atomic planar density.

Subsequently, a first metal gate electrode 57 may be formed over the gate dielectric layer 56.

The first metal gate electrode 57 may be formed by a series of processes of forming a first conductive material that fills the trench 55 over the gate dielectric layer 56, and then performing a recess process onto the first conductive material. The recess process may include a dry etching process, for example, an etch-back process.

For example, the first metal gate electrode 57 may include titanium nitride (TIN). The first metal gate electrode 57 may be formed by an Atomic Layer Deposition (ALD) process or a Chemical Vapor Deposition (CVD) process. According to another embodiment of the present disclosure, the first metal gate electrode 17 may include a stacked structure of a metal nitride excluding titanium nitride or a metal nitride including titanium nitride. According to another embodiment of the present disclosure, the first metal gate electrode 17 may include a metal material. For example, the metal may include a low-resistance metal material, such as molybdenum (Mo), tantalum (Ta), and titanium (Ti).

Referring to FIG. 4C, a dielectric oxide layer 58A and 58B may be formed over the first metal gate electrode 57 and the first gate dielectric layer 56 that is exposed by the first metal gate electrode 57. The dielectric oxide layer 58A and 58B may be formed conformally with a uniform thickness in the upper portion of the first metal gate electrode 57 and the upper portion of the sidewall of the first gate dielectric layer 56. The dielectric oxide layer 58A and 58B may include a first portion 58A disposed over the first metal gate electrode 57 and a second portion 58B disposed in the upper portion of the sidewall of the first gate dielectric layer 56. The first portion 58A and the second portion 58B may be a single structure that extends continuously.

For example, the dielectric oxide layer 58A and 58B may be formed by a plasma oxidation process. The plasma oxidation process may cause only surface oxidation of the first metal gate electrode 57, and deterioration in the resistance that may be caused due to the oxidation may not occur. Also, the plasma oxidation process may have a lower oxygen enhanced diffusion (OED) effect than that of a thermal oxidation process, preventing junction leakage current.

According to another embodiment of the present disclosure, the dielectric oxide layer 58A and 58B may be formed through a deposition process, a radical oxidation process, or an ion implantation process.

Referring to FIG. 4D, a second metal gate electrode 59 may be formed over the first portion 58A of the dielectric oxide layer. The second metal gate electrode 59 may be formed by a series of processes of forming a second conductive material that fills the trench 55 over the first portion 58A of the dielectric oxide layer, and then performing a recess process onto the second conductive material. The recess process may include a dry etching process, for example, an etch-back process.

The second metal gate electrode 59 may include the same metal as the first metal gate electrode 57. The second metal gate electrode 59 may include a metal or a metal nitride. For example, the metal material may include a low-resistance metal material, such as molybdenum (Mo), tantalum (Ta), and titanium (Ti). For example, the metal nitride may include titanium nitride (TIN). The second metal gate electrode 59 may be formed by an Atomic Layer Deposition (ALD) process or a Chemical Vapor Deposition (CVD) process.

Referring to FIG. 4E, a semiconductor material layer 60A may be formed to gap-fill the trench 55 over the second metal gate electrode 59 and the hard mask layer 54. The semiconductor material layer 60A may include a conductive semiconductor material. For example, the semiconductor material layer 60A may include a polysilicon material.

Referring to FIG. 4F, an annealing process ANL indicated by the arrows, may be performed. Therefore, the first portion 58A (see FIG. 4E) of the dielectric oxide layer disposed between the first and second metal gate electrodes 57 and 59 may be replaced with a conductive metal oxide electrode 61. For example, the annealing process ANL may be performed in an atmosphere of N₂, O₂, NH₃, H₂, SiH₄, or a mixed gas thereof.

The metal oxide electrode 61 may be replaced with a conductive metal oxide, as the metal in the first and second metal gate electrodes 57 and 59 and the oxygen in the first portion 58A of the dielectric oxide layer are diffused into each other by the annealing process ANL. Also, the first and second metal gate electrodes 57 and 59 may be crystallized by the annealing process ANL. Moreover, the first and second metal gate electrodes 57 and 59 may have an effect of increasing the flat band voltage Vfb through oxygen absorption during the annealing process ANL.

The thickness of the metal oxide electrode 61 may be thinner than the thickness of the first portion 58A of the dielectric oxide. The thickness of the metal oxide electrode 61 may be thinner than the thicknesses of the first and second metal gate electrodes 57 and 59.

The second portion 58B (see FIG. 4E) of the dielectric oxide excluding the metal oxide electrode 61 may be the second gate dielectric layer 58.

Referring to FIG. 4G, a semiconductor gate electrode 60 may be formed. An etching process may be performed onto the semiconductor material layer 60A of FIG. 4F to form the semiconductor gate electrode 60.

Referring to FIG. 4H, a gate capping layer 62 that gap-fills the trench 55 may be formed over the semiconductor gate electrode 60. Forming the gate capping layer 62 may include forming a dielectric material that gap-fills the trench 55 over the semiconductor gate electrode 60, and etching the dielectric material targeting to expose the surface of the hard mask layer 54. For example, the etching process may be performed as a planarization process including, for example, a Chemical Mechanical Polishing (CMP) process or an etch-back process.

For example, the gate capping layer 62 may include silicon nitride or silicon oxide.

Subsequently, the first and second doped regions 63 and 64 may be formed through an impurity ion implantation process of implanting an impurity into the substrate 51, i.e., the active region 53.

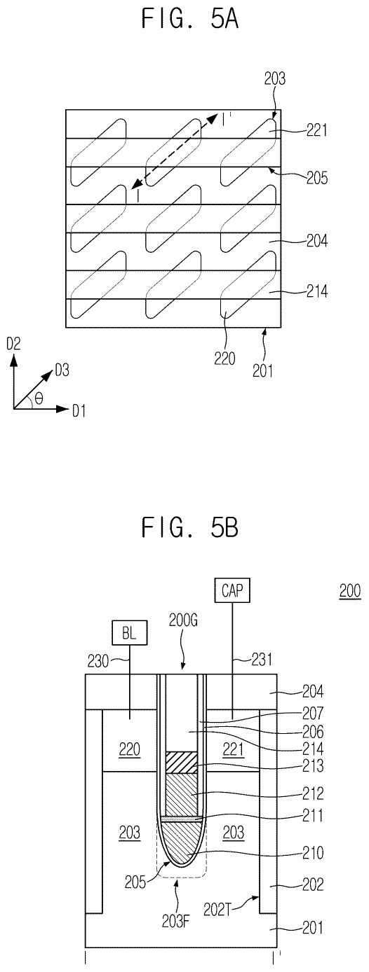

FIG. 5A is a plan view illustrating a semiconductor device in accordance with another embodiment of the present disclosure. FIG. 5B is a cross-sectional view illustrating the semiconductor device in accordance with the embodiment of the present disclosure. FIG. 5B is a cross-sectional view taken along a line I-I′ shown in FIG. 5A.

Referring to FIGS. 5A and 5B, the semiconductor device 200 may include a substrate 201 and a buried gate structure 200G embedded in the substrate 201, a first doped region 220, and a second doped region 221. The buried gate structure 200G and the first and second doped regions 220 and 221 may constitute a cell transistor. The cell transistor may improve the short channel effect due to the buried gate structure.

The semiconductor device 200 may be a portion of a memory cell. For example, the semiconductor device 200 may be a portion of a memory cell of a Dynamic Random Access Memory (DRAM). The semiconductor device 200 may include a bit line BL and a memory storage element CAP that are electrically connected to the substrate 201.

The bit line BL may be electrically connected to the first doped region 220, and the memory storage element CAP may be electrically connected to the second doped region 221. The bit line BL may be electrically connected to the first doped region 220 through a bit line node 230, and the memory storage element CAP may be electrically connected to the second doped region 221 through a storage node 231. The bit line BL and the memory storage element CAP may be disposed at a higher level than the buried gate structure 200G. The bit line BL and the memory storage element CAP may be disposed at different levels. The memory storage element CAP may be disposed at a higher level than the bit line BL. The memory storage element CAP may include a capacitor. According to another embodiment of the present disclosure, the memory storage element CAP may be a thyristor, a phase change material, a Magnetic Tunnel Junction (MTJ), or a variable resistance material.

The substrate 201 may be a material appropriate for semiconductor processing. The substrate 201 may include a semiconductor substrate.

An isolation layer 202 and active regions 203 may be formed in the substrate 201. The active regions 203 may be defined by the isolation layer 202. The isolation layer 202 may be a Shallow Trench Isolation (STI) region that is formed by a trench etching process. The isolation layer 202 may be formed by filling a shallow trench, for example, an isolation trench 202T, with a dielectric material. The isolation layer 202 may include silicon oxide, silicon nitride, or a combination thereof.

The active regions 203 may be formed of strips and may be disposed in the form of an array. The array of the active regions 203 may include a row array and/or a column array. The row array of active regions 203 may include active regions 203 that are disposed in the first direction D1. The column array of active regions 203 may include active regions 203 that are disposed in the second direction D2. The longitudinal direction of the active regions 203, i.e., a third direction D3, may be non-orthogonal to the first direction D1 and the second direction D2 to form an intersection angle θ. The intersection angle θ between the first direction D1 and the third direction D3 of each active region 103 may range from approximately 10° to 80°, but the embodiments of the present disclosure are not limited thereto. The range of the intersection angle θ may be affected by such parameters as the area of each active region 203, the line width of the bit line, and the line width of the buried gate structure 200G. From the perspective of a top view, the cross-section of the individual active regions 203 may be a parallelogram, for example, a parallelogram including rounded edges.

The active regions 203 may be disposed in the third direction D3.

A trench 205 may be formed in the substrate 201. The trench 205 may be formed by using the hard mask layer 204 as an etching barrier and etching the substrate 201. From the perspective of the plan view of FIG. 5A, the trench 205 may be a line shape extending in the first direction D1. The trench 205 may be a line shape crossing the active regions 203 and the isolation layer 202. One trench 205 may be formed in each active region 203.

The trenches 205 may be spaced apart from each other in the second direction D2. The depth of each trench 205 may be shallower than the depth of the isolation trench 202T. The bottom portion of the trench 205 may have a curvature. The trench 205 may be a space where the buried gate structure 200G is formed and may be referred to as a ‘gate trench 205’.

A fin 203F may be formed below the trench 205. The fin 203F may be formed by additionally etching the bottom surface of the trench 205 of the isolation layer 202 to form a height difference between the bottom surface of the trench 205 of the active region 203 and the bottom surface of the trench 205 of the isolation layer 202. The fin 203F may be called a saddle fin. The fin 203F may increase the channel width and improve the electrical characteristics.

According to another embodiment of the present disclosure, the fin 203F may be omitted.

The first doped region 220 and the second doped region 221 may be formed in the active regions 203. The first doped region 220 may be formed in the active region 203 on one side of the buried gate structure 200G, and the second doped region 221 may be formed in the active region 203 on an opposite side of the buried gate structure 200G. The first doped region 220 and the second doped region 221 may be the regions doped with a conductive dopant. For example, the conductive dopant may include phosphorus (P), arsenic (As), antimony (Sb), or boron (B). The first doped region 220 and the second doped region 221 may be doped with dopants of the same conductivity type.

The first doped region 220 and the second doped region 221 may be disposed in the active regions 203 on both sides of the trench 205, respectively. The first doped region 220 and the second doped region 221 may be spaced apart from each other by the trench 205. The bottom surfaces of the first doped region 220 and the second doped region 221 may be disposed at a predetermined depth from the top surface of the substrate 201. The bottom surfaces of the first doped region 220 and the second doped region 221 may be higher than the bottom surface of the trench 205. The first doped region 220 may be referred to as a ‘first source/drain region 220’, and the second doped region 221 may be referred to as a ‘second source/drain region 221’. A channel may be defined between the first doped region 220 and the second doped region 221 by the buried gate structure 200G. The channel may be defined along the profile of the trench 205.

The buried gate structure 200G may be embedded in the trench 205. The buried gate structure 200G may be disposed in the active region 203 between the first doped region 220 and the second doped region 221 to extend into the isolation layer 202. The bottom surface of the portion of the buried gate structure 200G disposed in the active region 203 and the bottom surface of the portion of the buried gate structure 200G disposed in the isolation layer 202 may be disposed at different levels. When the fin region 203F is omitted, the bottom surface of the portion of the buried gate structure 200G disposed in the active region 203 and the bottom surface of the portion of the buried gate structure 200G disposed in the isolation layer 202 may be disposed at the same level.

The buried gate structure 200G may include a first gate dielectric layer 206 suitable for covering the bottom surface and sidewall of the trench 205, a second gate dielectric layer 207 overlapping with a portion of the sidewall of the trench 205 on the sidewall of the first gate dielectric layer 206, a first metal gate electrode 210 suitable for filling the lower portion of the trench 205 over the first gate dielectric layer, a metal oxide electrode 211 over the first metal gate electrode 210, a second metal gate electrode 212 over the metal oxide electrode 211, a semiconductor gate electrode 213 over the second metal gate electrode 212, and a gate capping layer 214 formed over the semiconductor gate electrode 213. The first metal gate electrode 210 may be referred to as a ‘first buried conductive layer 210’. The stacked structure of the metal oxide electrode 211, the second metal gate electrode 212 and the semiconductor gate electrode 213 may be referred to as a ‘second buried conductive layer’.

The first gate dielectric layer 206 may be conformally formed along the bottom surface and the inner wall of the trench 205. The first gate dielectric layer 206 may include silicon oxide, silicon nitride, silicon oxynitride, a high-k material, or a combination thereof. The high-k material may include a material having a greater dielectric constant than the dielectric constant of silicon oxide. For example, the high-k material may include a material having a greater dielectric constant than approximately 3.9. In another embodiment, the high-k material may include a material having a greater dielectric constant than approximately 10. In yet another embodiment, the high-k material may include a material having a dielectric constant of approximately 10 to 30. The high-k material may include at least one metallic element. The high-k material may include a hafnium-containing material. The hafnium-containing material may include hafnium oxide, hafnium silicon oxide, hafnium silicon oxynitride, or a combination thereof. According to another embodiment of the present disclosure, the high-k material may include lanthanum oxide, lanthanum aluminum oxide, zirconium oxide, zirconium silicon oxide, zirconium silicon oxynitride, aluminum oxide, or a combination thereof. Other known high-k materials may be selectively used as the high-k material. The first gate dielectric layer 206 may include a metal oxide.

The first metal gate electrode 210 may fill a portion of the trench 205. The first metal gate electrode 210 may include a metal or a metal nitride. For example, the metal may include a low-resistance metal material, such as molybdenum (Mo), tantalum (Ta), and titanium (Ti). For example, the metal nitride may include titanium nitride (TIN). The outer wall of the first metal gate electrode 210 may be covered by the first gate dielectric layer 206. That is, only the first gate dielectric layer 206 may remain between the first metal gate electrode 210 and the inner wall of the trench 205.

The metal oxide electrode 211 may be disposed over the first metal gate electrode 210. The metal oxide electrode 211 may be a conductive material including the same metal as those of the first and second metal gate electrodes 210 and 212. The thickness of the metal oxide electrode 211 may be thinner than the thickness of each of the first and second metal gate electrodes 210 and 212.

For example, when the first metal gate electrode 210 is of titanium nitride (TiN), the metal oxide electrode 211 may be of conductive titanium oxide (TiₓO_{y}), but the embodiments of the present disclosure are not limited thereto.

Both sides of the metal oxide electrode 211 may contact the second gate dielectric layer 207. More specifically, the second gate dielectric layer 207 may contact the side edge portions of the top surface of the metal oxide electrode 211. The first and second gate dielectric layers 206 and 207 may be disposed between the metal oxide electrode 211 and the inner wall of the trench 205.

A second metal gate electrode 212 may be formed over the metal oxide electrode 211. The second metal gate electrode 212 may be the same material as that of the first metal gate electrode 210. For example, the second metal gate electrode 212 may include titanium nitride.

A semiconductor gate electrode 213 may be formed over the second metal gate electrode 212. For example, the semiconductor gate electrode 213 may include polysilicon. The thickness of the semiconductor gate electrode 213 may be thinner than the thickness of each of the first and second metal gate electrodes 210 and 212. The thickness of the semiconductor gate electrode 213 may be thicker than the thickness of the metal oxide electrode 211.

The semiconductor gate electrode 213 may overlap with the first and second doped regions 220 and 221 in a direction parallel to the surface of the substrate 201.

A gate capping layer 214 may be formed over the semiconductor gate electrode 213. The gate capping layer 214 may prevent oxidation of the semiconductor gate electrode 213. The gate capping layer 214 may be formed in the trench 205 to electrically insulate the upper structure, such as the contact and the conductive line, from the lower gate electrode. According to an embodiment of the present disclosure, the upper surface of the gate capping layer 214 may be disposed at the same level as the upper surface of the hard mask layer 204. According to another embodiment of the present disclosure, the upper surface of the gate capping layer 214 may be disposed at the same level as the upper surface of the substrate 201.

The gate capping layer 214 may include a dielectric material. The gate capping layer 214 may include silicon nitride or silicon oxide, but the embodiments of the present disclosure are not limited thereto. According to another embodiment of the present disclosure, the gate capping layer 214 may include a low-k material. The gate capping layer 214 may be formed as a single layer. According to another embodiment of the present disclosure, the gate capping layer 214 may be formed to have a multi-layer structure of different materials.

The second gate dielectric layer 207 may contact the metal oxide electrode 211, and both sides of the second metal gate electrode 212, the semiconductor gate electrode 213 and the gate capping layer 214. The second gate dielectric layer 207 may be disposed between the metal oxide electrode 211, the second metal gate electrode 212 and the semiconductor gate electrode 213, and the inner side of the trench 205. The second gate dielectric layer 207 may include the same material as that of the first gate dielectric layer 206. For example, the second gate dielectric layer 207 may include silicon oxide.

Referring to FIGS. 5A and 5B, the semiconductor device 200 may include a plurality of memory cells, and the neighboring memory cells may be spaced apart from each other by the isolation layer 202. One memory cell may be formed over one active region 203, and this may be referred to as a memory cell of a ‘1G1A (one-Gate-one Active) structure.’ In the memory cell of the 1G1A structure, a bit line BL may be coupled to one active region 203. Therefore, one memory cell may be coupled to one bit line BL. The memory cell of the 1G1A structure may include 1T1C (one Transistor-one Capacitor). As a comparative example, in a general Dynamic Random Access Memory (DRAM), two memory cells may be formed in one active region, and two gate electrodes may be formed in one active region, and two neighboring memory cells may share one bit line.

According to the embodiment of the present disclosure, the Gate-Induced Drain Leakage (GIDL) may be reduced by increasing the thickness of a gate dielectric layer which is adjacent to a junction.

While the present invention has been described with respect to specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A semiconductor device comprising:
a trench formed in a substrate;
a first gate dielectric layer covering a bottom surface and sidewalls of the trench;
a first buried conductive layer filling a bottom portion of the trench over the first gate dielectric layer;
a second buried conductive layer including a conductive metal oxide over the first buried conductive layer; and
a second gate dielectric layer disposed between the second buried conductive layer and the first gate dielectric layer.

2. The semiconductor device of claim 1, wherein the first buried conductive layer includes a metal or a metal nitride.

3. The semiconductor device of claim 1, wherein the second buried conductive layer includes a stacked structure of a conductive metal oxide, a metal nitride, and polysilicon, or a stacked structure of a conductive metal oxide, a metal, and polysilicon.

4. The semiconductor device of claim 1, wherein the conductive metal oxide includes the same metal as the first buried conductive layer.

5. The semiconductor device of claim 1, wherein the first buried conductive layer includes titanium nitride.

6. The semiconductor device of claim 1, wherein the conductive metal oxide includes titanium oxide.

7. The semiconductor device of claim 1, wherein the second gate dielectric layer includes silicon oxide.

8. The semiconductor device of claim 1, further comprising:
a fin region below the first buried conductive layer,
wherein an upper surface and sidewalls of the fin region are covered by the first gate dielectric layer.

9. The semiconductor device of claim 1, further comprising a gate capping layer suitable for filling the remaining portion of the trench over the second buried conductive layer.

10. The semiconductor device of claim 1, further comprising first and second conductive regions in the substrate on both sides of the trench.

11. The semiconductor device of claim 1, wherein the substrate includes a plurality of active regions that are spaced apart from each other, and
wherein the trench is disposed in each of the active regions.
